(19) United States
(12) Patent Application Publication
(10) Pub. No.: US 2026/0278234 A1
(43) Pub. Date: Sep. 17, 2026

(54) AUTOMATED CHIP DESIGN USING REINFORCEMENT LEARNING

(71) Applicant: XgenSilicon Inc., Santa Clara, CA (US)

(72) Inventors: Bin Xu, Cupertino, CA (US); Ravindra Ganti, Mountain House, CA (US)

(21) Appl. No.: 19/564,003

(22) Filed: Mar. 11, 2026

Related U.S. Application Data
(60) Provisional application No. 63/770,705, filed on Mar. 12, 2025.

(51) Int. Cl. G06F 30/392

(52) U.S. Cl. CPC G06F 30/392

(57) ABSTRACT

The present disclosure relates to a computer-implemented method for automated generation of ASIC design files for machine learning workloads. A computing system receives a representation of one or more machine learning models, along with an initial configuration of configurable hardware elements and an initial mapping of workloads associated with model execution. Based on simulation of the initial configuration and mapping, one or more ASIC performance metrics are obtained. The system updates the hardware configuration and/or workload mapping according to the performance metrics and predefined design constraints. Simulation and update operations are iteratively performed until a termination condition is satisfied, producing progressively improved configurations or mappings. Upon completion, one or more ASIC design files are generated based on the final configuration and/or mapping. The disclosed method enables efficient, constraint-aware optimization of ASIC designs tailored to machine learning model execution.

### CROSS-REFERENCE TO RELATED APPLICATIONS

This application claims the benefit of and priority to U.S. Provisional Patent Application No. 63/770,705, filed on Mar. 12, 2025, and entitled “FULLY AUTOMATED ASIC CHIP DESIGN USING REINFORCEMENT LEARNING,” the entire disclosure of which is hereby incorporated by reference.

### TECHNICAL FIELD

The present disclosure relates to integrated circuit design automation. More particularly, the present disclosure relates to machine-learning-based techniques, including reinforcement learning, for automated design of semiconductor chips like application-specific integrated circuit (ASIC) chips.

### BACKGROUND

An application-specific integrated circuit (ASIC) is an integrated circuit designed to implement a particular application or class of applications. An ASIC may include computational circuitry, memory, and interconnect hardware elements that support execution of a target workload.

An application workload may be represented as a set of operations or tasks, for example in the form of a computation graph. Mapping a workload to an ASIC generally involves assigning such operations to hardware elements and determining how execution and data flow are organized across the hardware.

ASIC design outcomes can depend on both the configuration of hardware elements and the mapping of the workload to those elements, and different combinations may be evaluated to meet design objectives and constraints.

ASIC can offer advantages for certain workloads, such as improved performance and/or reduced power consumption compared to more general-purpose processing solutions. However, developing an ASIC typically involves substantial engineering effort across multiple stages of a design and implementation flow, and may require repeated iterations to evaluate candidate architectures and implementations. Thus, a typical ASIC design process may be time consuming, cumbersome, and costly.

### SUMMARY

Designing an application-specific integrated circuit (ASIC) for a target workload involves selecting hardware configurations (e.g., computational circuitry, memory, and interconnect resources) and determining workload mappings (e.g., how workload components are mapped to such resources). In many implementations, candidate ASIC designs are evaluated using simulation to obtain one or more performance metrics, such as power consumption, performance, and silicon die area consumption (PPA).

Typical approaches to ASIC design involve iterative exploration of hardware configurations and workload mappings according to the performance metrics. Because many hardware configurations choices are coupled with workload mapping choices, evaluating candidate ASIC design often involves repeated simulations over multiple iterations, especially when multiple design constraints apply. Such approaches require pre-defined rules to describe the constraints and large human involvement, e.g., to define constraints, tune parameters, and review results. Therefore, a typical ASIC design process may have low efficiency and may be time consuming.

The present disclosure addresses the above deficiency by providing an automated ASIC chip design method that jointly optimizes multiple and coupled parameters using a machine learning technique. The method can run the optimization process by automatically and simultaneously tunning the hardware configurations and workload mappings while satisfying multiple design constraints. While this disclosure uses ASIC design as an example to illustrate the automated design process based on machine learning techniques, it is understood that the techniques described in this disclosure can also be applied to any other chip design processes, not limited to ASIC chip design. For example, it can be applied to programmable circuit designs, chipset designs, memory designs, communication circuitry designs, etc.

The present disclosure provides a computer-implemented method for automated generation of one or more ASIC design files. The method can be performed by a computing system having at least one processor and memory. The method includes receiving a representation of at least one machine learning model and obtaining an initial configuration of a set of configurable hardware elements and an initial mapping of workloads to the set of configurable hardware elements. The workloads are associated with tasks performed during execution of the at least one machine learning model. The method further includes obtaining, based on simulation using the initial configuration and the initial mapping, one or more ASIC performance metrics. The method further includes updating at least one of the initial configuration or the initial mapping to obtain at least one of an updated configuration of the set of configurable hardware elements or an updated mapping, based on the one or more ASIC performance metrics and one or more design constraints. The method further includes iteratively performing, until a termination condition is satisfied, obtaining one or more updated ASIC performance metrics based on simulation using at least one of: the initial configuration or the updated configuration, or the initial mapping or the updated mapping; and determining at least one of a further updated configuration of the set of configurable hardware elements or a further updated mapping based on the one or more updated ASIC performance metrics and the one or more design constraints. The method further includes generating the one or more ASIC design files based on at least one of the last updated configuration of the set of configurable hardware elements and the last updated mapping.

Therefore, the present disclosure reduces the reliance on human involvement and explores candidate designs under multiple design constraints. It further produces ASIC design files based on a final/optimized hardware configuration and workload mapping.

### BRIEF DESCRIPTION OF THE DRAWINGS

The present application can be best understood by reference to the embodiments described below taken in conjunction with the accompanying drawing figures, in which like parts may be referred to by like numerals.

FIG. 1 illustrates an example parameterized hardware architecture including configurable compute subsystems, memory, and interconnect elements, in accordance with examples disclosed herein.

FIG. 2 illustrates an example reinforcement learning process for workload mapping and hardware configuration optimization for ASIC chip design, in accordance with examples disclosed herein.

FIG. 3 illustrates a flowchart of an example automated generation of ASIC design files, in accordance with examples disclosed herein.

FIG. 4 illustrates an example of computing system, in accordance with examples disclosed herein.

### DETAILED DESCRIPTION

To provide a more thorough understanding of various embodiments of the present invention, the following description sets forth numerous specific details, such as specific configurations, parameters, examples, and the like. It should be recognized, however, that such description is not intended as a limitation on the scope of the present invention but is intended to provide a better description of the exemplary embodiments.

Throughout the specification and claims, the following terms take the meanings explicitly associated herein, unless the context clearly dictates otherwise:

The phrase “in one embodiment” as used herein does not necessarily refer to the same embodiment, though it may. Thus, as described below, various embodiments of the disclosure may be readily combined, without departing from the scope or spirit of the invention.

As used herein, the term “or” is an inclusive “or” operator and is equivalent to the term “and/or,” unless the context clearly dictates otherwise.

The term “based on” is not exclusive and allows for being based on additional factors not described unless the context clearly dictates otherwise.

As used herein, and unless the context dictates otherwise, the term “coupled to” is intended to include both direct coupling (in which two elements that are coupled to each other contact each other) and indirect coupling (in which at least one additional element is located between the two elements). Therefore, the terms “coupled to” and “coupled with” are used synonymously. Within the context of a networked environment where two or more components or devices are able to exchange data, the terms “coupled to” and “coupled with” are also used to mean “communicatively coupled with”, possibly via one or more intermediary devices. The components or devices can be optical, mechanical, and/or electrical devices.

Although the following description uses terms “first,” “second,” etc. to describe various elements, these elements should not be limited by the terms. These terms are only used to distinguish one element from another. For example, a first model could be termed a second model and, similarly, a second model could be termed a first model, without departing from the scope of the various described examples. The first model and the second model can both be models and, in some cases, can be separate and different models.

In addition, throughout the specification, the meaning of “a”, “an”, and “the” includes plural references, and the meaning of “in” includes “in” and “on”.

Although some of the various embodiments presented herein constitute a single combination of inventive elements, it should be appreciated that the inventive subject matter is considered to include all possible combinations of the disclosed elements. As such, if one embodiment comprises elements A, B, and C, and another embodiment comprises elements B and D, then the inventive subject matter is also considered to include other remaining combinations of A, B, C, or D, even if not explicitly discussed herein. Further, the transitional term “comprising” means to have as parts or members, or to be those parts or members. As used herein, the transitional term “comprising” is inclusive or open-ended and does not exclude additional, unrecited elements or method steps.

As used in the description herein and throughout the claims that follow, when a system, engine, server, device, module, or other computing element is described as being configured to perform or execute functions on data in a memory, the meaning of “configured to” or “programmed to” is defined as one or more processors or cores of the computing element being programmed by a set of software instructions stored in the memory of the computing element to execute the set of functions on target data or data objects stored in the memory.

It should be noted that any language directed to a computer should be read to include any suitable combination of computing devices or network platforms, including servers, interfaces, systems, databases, agents, peers, engines, controllers, modules, or other types of computing devices operating individually or collectively. One should appreciate the computing devices comprise a processor configured to execute software instructions stored on a tangible, non-transitory computer readable storage medium (e.g., hard drive, FPGA, PLA, solid state drive, RAM, flash, ROM, or any other volatile or non-volatile storage devices). The software instructions configure or program the computing device to provide the roles, responsibilities, or other functionality as discussed below with respect to the disclosed apparatus. Further, the disclosed technologies can be embodied as a computer program product that includes a non-transitory computer readable medium storing the software instructions that causes a processor to execute the disclosed steps associated with implementations of computer-based algorithms, processes, methods, or other instructions. In some embodiments, the various servers, systems, databases, or interfaces exchange data using standardized protocols or algorithms, possibly based on HTTP, HTTPS, AES, public-private key exchanges, web service APIs, known financial transaction protocols, or other electronic information exchanging methods. Data exchanges among devices can be conducted over a packet-switched network, the Internet, LAN, WAN, VPN, or other type of packet switched network; a circuit switched network; cell switched network; or other type of network.

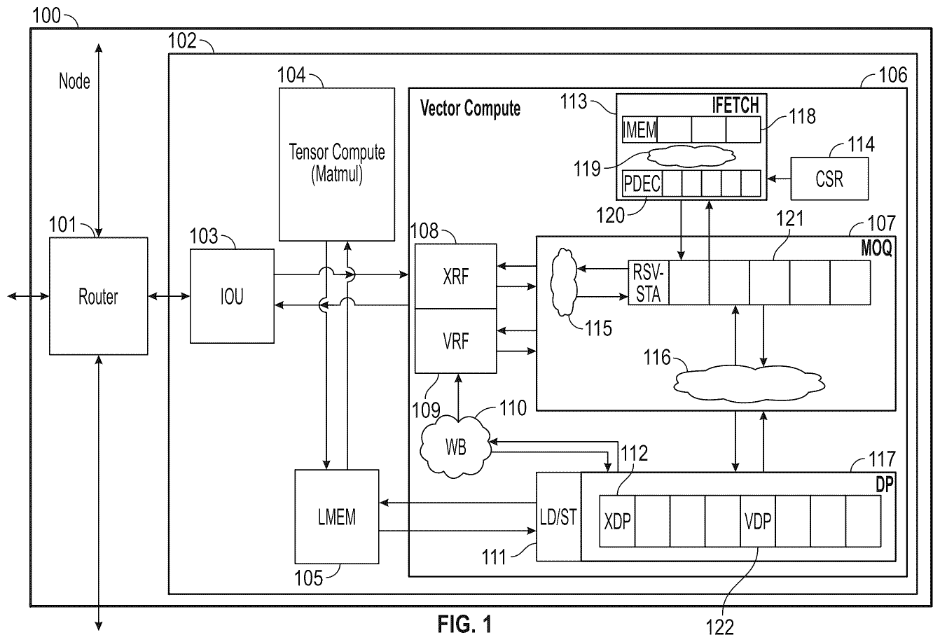

FIG. 1 illustrates an example computational node 100 including a router 101, a boundary or wrapper 102, an input/output unit (IOU) 103, a tensor compute subsystem 104, local memory (LMEM) 105, and a vector compute subsystem 106. Each of elements 100-106 can be a configurable hardware element associated with adjustable design parameters. As a configurable hardware element, the adjustable design parameters associated with node 100 can include, for example, the number of tensor compute subsystem 104 and the number of vector compute subsystem 106. For example, node 100 can be a parameterized hardware architecture formed by configurable hardware elements associated with architecture-level adjustable design parameters such as a compute dimension, a memory capacity, a bandwidth, a data-unit width, a port count, an operating voltage, an operating frequency, and/or other parameters.

With reference to FIG. 1, router 101 can communicate data between node 100 and other nodes and/or other components via an interconnect fabric. For example, router 101 can be implemented as a network-on-chip (NoC) router, a switch, or another interconnect interface. As a configurable hardware element, the adjustable design parameters associated with router 101 can be data-unit width for routed transfers or number of ports of the interconnect router.

IOU 103 can provide input/output functionality for the node 100. For example, IOU 103 can include one or more bus interfaces, direct-memory-access (DMA) logic, streaming interfaces, or other data-movement circuitry.

The tensor compute subsystem 104 can perform tensor or matrix-oriented computations. A tensor is a data structure or an object that can include or represent scalars, vectors, and/or matrixes, and/or other higher dimensional data elements. For example, the tensor compute subsystem 104 can include a matrix-multiply engine, a systolic array, or a multiply-accumulate (MAC) array. As a configurable hardware element, the adjustable design parameters associated with tensor compute subsystem 104 can include, for example, row dimension, column dimension, quantization, or any other parameters related to tensor-based computation.

LMEM 105 can store data locally within node 100. For example, LMEM 105 can include one or more static random-access memory (SRAM) banks, read-only memory (ROM), scratchpad memory, flash memory, multi-ported local storage, and/or any volatile or non-volatile memory. As a configurable hardware element, the adjustable design parameters associated with LMEM 105 can include, for example, storage capacity, the number of access ports, memory bandwidth, memory read/write speed, or any other memory-related parameters.

Vector compute subsystem 106 can perform vector-oriented computations and, in an illustrated example, includes one or more data paths and control structures. A vector is a data structure having a single dimension of numeric data elements. The vector compute subsystem 106 includes a scalar register file (XRF) 108 and a vector register file (VRF) 109 that can store scalar and vector operands, respectively. The vector compute subsystem 106 further includes a load/store unit (LD/ST) 111 that can access memory, for example, to perform load and store operations between LMEM 105 and one or more registers or internal buffers. As a configurable hardware element, the adjustable design parameters associated with vector compute subsystem 106 can include, for example, a queue capacity for pending vector operations, an issue width for dispatching vector operations, a write-back bandwidth, a load-store data width, a number of instruction decoders, a number of reservation stations, a number of read and write ports of register file, a number of scalar execution units, a number of vector execution units, a number of memory read and write ports, and/or any other vector computation related parameters.

As a configurable hardware element, the adjustable design parameters associated with XRF 108 can include, for example, a number of scalar register read ports and/or a number of scalar register write ports. As a configurable hardware element, the adjustable design parameters associated with VRF 109 can include, for example, a number of vector register read ports and/or a number of vector register write ports.

Vector compute subsystem 106 includes one or more data paths (DPs) 117 that includes one or more scalar data paths (XDP) 112 and one or more vector data paths (VDP) 122. XDP(s) 112 can facilitate execution of scalar operations, and VDP(s) 122 can facilitate execution of vector operations. As a configurable hardware element, the adjustable design parameters associated with DP(s) 117 can include the number of XDP(s) 112, the number of VDP(s) 122, vector length, and any other scalar or vector computation related parameters.

Vector compute subsystem 106 can also include control and status registers (CSR) 114 that can store configuration and/or status information. For example, the CSR 114 can store configuration values, mode settings, performance counters, and/or other control/state information.

With reference still to FIG. 1, vector compute subsystem 106 includes instruction fetch circuitry 113 (IFETCH) coupled with instruction storage 118. For example, instruction storage 118 can be an instruction memory (IMEM), which stores instructions. Front-end logic 119 and control logic 120 (POEC) can support instruction handling and operation sequencing within vector compute subsystem 106. As a configurable hardware element, the adjustable design parameters associated with IFETCH 113 can include, for example, size of IFETCH 113, speed of the IFETCH 113, bandwidth, etc. As a configurable hardware element, the adjustable design parameters associated with POEC 120 can include, for example, station count parameter (STANUM).

Vector compute subsystem 106 includes a queue or buffer region 107 (MOQ) configured to hold pending operations for execution. MOQ 107 is associated with one or more reservation stations 121 (RSVSTA). The XRF 108 and the VRF 109 are coupled to the queueing and scheduling structures, including the MOQ 107 and the reservation station circuitry, such that pending operations can be buffered and tracked prior to execution. For example, an entry in the MOQ 107 can identify one or more operations and associate each operation with source operands located in the XRF 108 and/or the VRF 109 and with a destination for subsequent result writeback.

With reference still to FIG. 1, MOQ 107 includes a scheduling and/or dispatch control logic 115 and execution-control logic 116. Scheduling and/or dispatch logic 115 and execution-control logic 116 can be coupled to the reservation stations 121 and can manage issuance and control of pending operations buffered by the queueing and scheduling structures. For example, logic 115 can include issue/dispatch control and related control logic, and logic 116 can include execution sequencing and/or pipeline control logic associated with operations issued from reservation station circuitry 121. As a configurable hardware element, the adjustable design parameters associated with MOQ 107 can include, for example, station count parameter (STANUM) of reservation stations 121.

Vector compute subsystem 106 further includes result-routing logic 110 (WB) which can write execution results to one or more destinations. For example, result-routing logic 110 can be implemented as a writeback stage, a writeback network, or arbitration circuitry that selects among multiple result sources and controls writes into the XRF 108 and/or the VRF 109.

As illustrated in FIG. 1, node 100 operates as an integrated computing unit in which interconnect, memory, and compute subsystems/components cooperate to execute workloads. Data can be communicated into and out of node 100 through router 101 and IOU 103, and locally stored information can be provided by LMEM 105. Within node 100, compute operations can be performed by tensor compute subsystem 104 and vector compute subsystem 106. The instruction handling is supported by IFETCH 113, coupled to instruction storage 118 and associated front-end/control logic 119 and 120. Pending operations can be buffered and managed using queue/buffer region 107 and reservation station circuitry 121. Such operations can be issued for execution by control logic 115 and 116 to data path circuitry 117 including scalar data paths 112 and vector data paths 122. Execution results can be routed by result-routing logic 110 for storage, forwarding, and/or writeback to architectural state, thus enabling coordinated operation of the components of node 100.

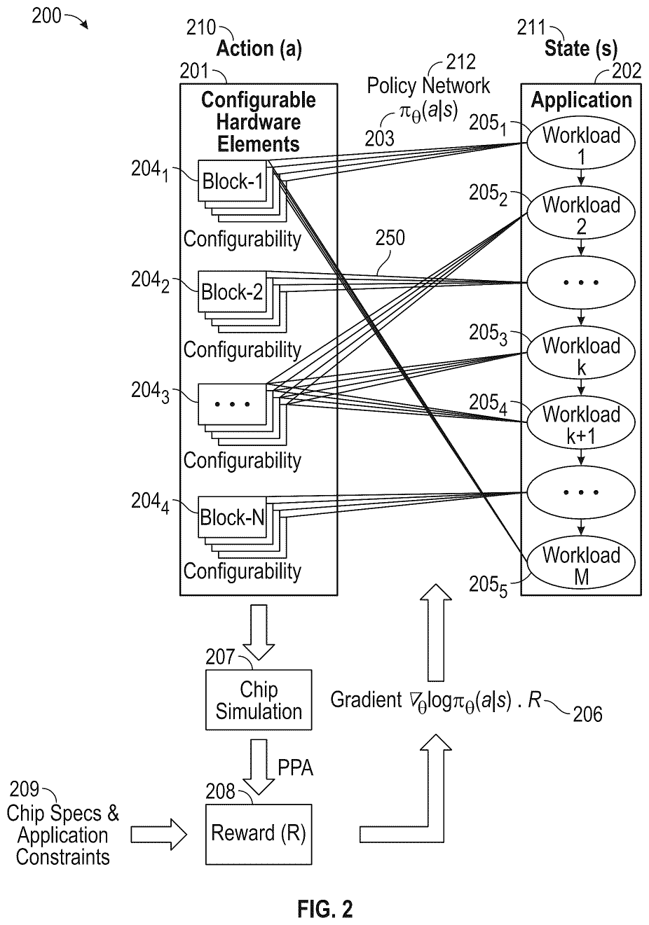

FIG. 2 illustrates an example reinforcement-learning-based optimization framework 200 for automated chip (e.g., ASIC) design. In this example, application 202 can represent a machine learning model (e.g., large language model, or LLM) and it can be received through an input portal by a computer system. The computer system can include at least a processor and memory to automate the designing of an ASIC chip for efficiently and effectively handling the workload associated with the machine learning model. The ASIC chip should be designed with certain constraints like power, performance, and area (PPA) while still be able to satisfy the computational needs imposed by the machine learning model in an improved or optimized manner.

With reference still to FIG. 2, application 202 can include a computation graph formed by subgraphs and operators that are assignable to the set of configurable hardware elements 201 (e.g., subsystems or elements 100-106 are examples of configurable hardware elements 201), which can also be received through the input portal by the computer system. Application 202 can be partitioned or represented as a set of workloads 205₁-205₅ (e.g., Workload-1 205₁, Workload-2 205₂, . . . , Workload-M 205₅), which can be associated with tasks performed during execution of application 202 (e.g., execution of a large language model for prediction). A policy network 212 is a function with adjustable parameters θ. Policy network 212 can be an artificial neural network that receives information associated with a state 211 (s) and produces an action 210 (a). State 211 can include the state of application 202. Action 210 can specify one or more design decisions for configurable hardware elements 201. For example, within a reinforcement learning method, action 210 can be produced according to a probability distribution π_{θ} that is associated with equation 203 (π_{θ}(a|s)) representing the policy network 212. In equation 203, a denotes action 210, s denotes state 211, θ denotes parameters of policy network 212, π_{θ} denotes probability distribution computed in equation 203. Equation 203 representing the policy network 212 can be computed by a computer system (e.g., having at least one processor and memory) to obtain a probability distribution π_{θ} that describes the probability of producing an action 210 given a state 211.

Action 210 can include configuration decisions for configurable blocks within configurable hardware elements 201 and mapping decisions that assign one or more workloads 205₁-205₅ to hardware blocks 204₁-204₄ (e.g., each can include one or more nodes 100 or a portion thereof in FIG. 1) of configurable hardware elements 201.

Configurable hardware elements 201 include one or more configurable blocks 204₁-204₄ (e.g., Block-1 204₁, Block-2 204₂, . . . , Block-N 204₄), each having configurability. The configurability can be associated with adjustable design parameters of one or more blocks 204₁-204₄. For example, adjustable design parameters can control various attributes like compute, memory, interconnect, precision, parallelism, bandwidth, or other architectural or microarchitectural attributes. The mapping portion of action 210 can specify how workloads 205₁-205₅ are placed, assigned, scheduled, or otherwise bound to blocks 204₁-204₄, including mapping multiple workloads to a same block to promote resource reuse.

In FIG. 2, Mappings 250 are shown as straight lines connecting hardware blocks (e.g., 204₁-204₄) and workloads (e.g., 205₁-205₅). Mappings 250 can include mappings between workloads 205₁-205₅ and hardware blocks 204₁-204₄. In one example, according to mapping 250, workload 205₁ can be mapped to hardware block 204₁, and workload 205₂ can be mapped to block 204₃.

In the example of FIG. 2, the selected configuration of hardware elements (e.g., blocks 204₁-204₄) and/or mapping (e.g., mapping 250) for configurable hardware elements 201 are evaluated using chip simulation 207, which generates performance metrics (e.g., PPA and/or other ASIC performance metrics) for the candidate design. The chip simulation can be performed using EDA design tools. For example, chip simulation 207 can perform waveform simulation of the workload (e.g., 205₁-205₅) on a hardware configuration. Chip simulation 207 can generate activity factors indicating how often circuit elements (e.g., logic gates and registers) switch states (e.g., ON or OFF) during execution of a workload. The computing system can obtain resistance-capacitance (RC) extraction data from a post-layout representation of the ASIC design. The computing system can use the activity factors and the RC extraction data as inputs to determine a power metric, which is a part of the ASIC performance metric. The ASIC performance metrics can be composite metrics derived from power, performance, and die area in accordance with the design constraints (e.g., constraints 209). The simulation outputs are used to derive a reward (e.g., reward 208 (R)), which can be computed based on chip specifications and application constraints 209. Chip specifications and application constraints 209 can include one or more design objectives and constraints, such as power constraints, performance constraints, or die area constraints. For instance, if the simulation outputs do not satisfy the design objectives and constraints, the reward 208 may have a negative value; and vice versa. In some examples, the reward 208 value can change based on how close the simulation outputs approaches the design objectives and constraints.

In some other examples, a surrogate approximator can be used in place of chip simulation 207 to predict one or more ASIC performance metrics, such as PPA. The surrogate approximator can be a neural network trained with training data. The training data can include, for example, input-output pairs. Inputs can include, for example, given workloads of the input model and outputs can include, for example, PPA of the post-layout ASIC design produced in chip simulation 207. The said neural network can include, for example, graph neural network (GNN). In some examples, policy network 212 can be trained by adjusting its parameters θ based on outputs of the surrogate approximator and responses of the hardware elements. In some examples, to avoid getting struck in local optima, the training of policy network 212 can include, for example, using a soft actor-critic for non-convex register-transfer level (RTL).

Reward 208 (e.g., derived from ASIC performance metrics and design constraints) is used as feedback to update policy network 212 using, for example, equation 206. In the illustrated example, equation 206 is shown as a gradient term (e.g., ∇_{θ}(log π_{θ}(a|s))·R). In equation 206, a denotes action 210, s denotes state 211, R denotes reward 208, θ denotes parameters of policy network 212, π_{θ} denotes probability distribution computed in equation 203, and ∇_{θ} denotes computing the gradient of π_{θ} with respect to θ. Equation 206 can be used to calculate the update of the parameters θ of policy network 212 based on reward 208. For example, log(π_{θ}(a|s)) produces a logarithmic function of the probability distribution of an action 210 (a) given a state 211 (s) according to equation 203. ∇_{θ}(log π_{θ}(a|s)) produces gradients of the logarithmic function with respect to parameters θ of policy network 212. The gradients can then be multiplied by reward 208 (R) using equation 206 to update parameters θ of policy network 212. Equation 206 indicates that the parameters θ of policy network 212 can be adjusted based on reward 208 to determine subsequent actions 210. It is understood that equation 206 is an example of obtaining feedback to adjust the policy network 212. Other methods or equations may also be used as a feedback to adjust the policy network 212 (including the mapping) and design parameters of configurable hardware elements 201.

In the example of FIG. 2, framework 200 can also include a critic network not shown in the figure. The critic network can evaluate action 210 by predicting a reward value resulting from action 210. For example, if the predicted reward value of a specific candidate action (e.g., a specific action 210) is high, the critic network can increase the probability (e.g., using equation (π_{θ}(a|s))) of this specific candidate action. Consequently, policy network 212 can choose to execute the specific candidate action based on the higher probability compared with other candidate actions. The critic network can be a neural network that is trained using a training data set and a target return value. The training data set of the critic network can be input-output pairs. Inputs of the pairs can be provided as the inputs to the current policy network (e.g., policy network 212), and outputs of the pairs can be the reward derived from an action (e.g., action 210) from the current policy network (e.g., policy network 212). In some examples, the training and execution of critic network can occur in parallel during policy network 212 updating iterations.

Framework 200 can be executed iteratively such that policy network 212 repeatedly proposes updated configuration and/or mapping decisions. For example, the candidate ASIC designs can be evaluated via simulation 207. Reward 208, recomputed based on the ASIC performance metrics and design constraints (e.g., constraints 209), can be used to provide feedback to update policy network 212 until a termination condition is satisfied.

The termination condition can be convergence of reward 208 or satisfaction of a design target. For example, when reward 208 is above a pre-defined threshold and/or does not increase (or with negligible increment) with more iterations (convergence), framework 200 can be terminated. In another example, when configurable hardware elements 201 and workload mapping satisfy a design target, framework 200 can be terminated. Other termination conditions can also be defined. After termination, one or more ASIC design files can be generated.

In some examples, if termination condition is not satisfied, framework 200 can be used to determine a further updated configuration (e.g., by adjusting, without receiving a user input, the respective adjustable design parameters) of the set of configurable hardware elements 201 or a further updated mapping based on updated ASIC performance metrics and design constraints 209. In some examples, framework 200 can keep the updated configuration of the set of configurable hardware elements fixed and be used to further update the updated mapping. In some other examples, in addition to update the updated mapping, framework 200 can be used to further update the updated configuration of the set of configurable hardware elements to have different values of design parameters.

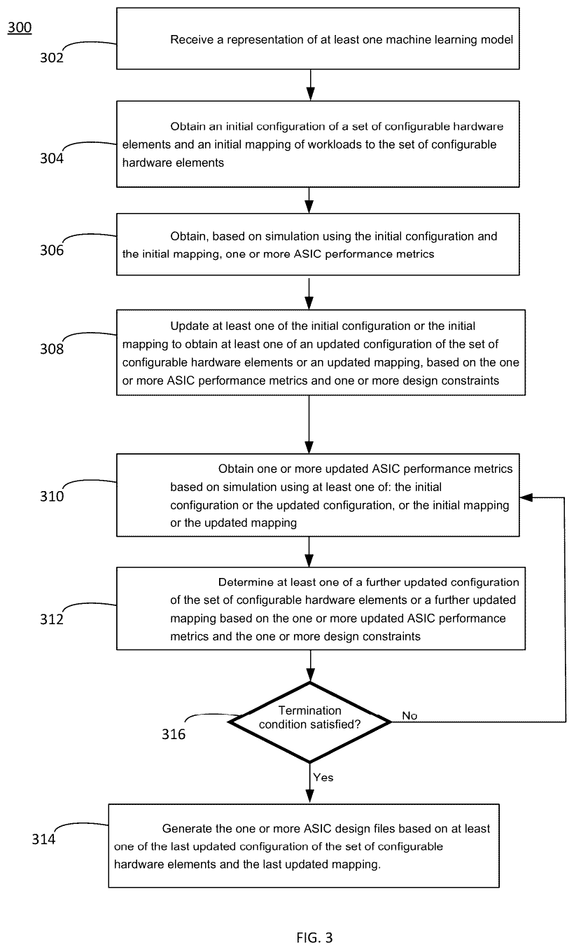

FIG. 3 illustrates an example computer-implemented process 300 for automated generation of one or more application-specific integrated circuit (ASIC) design files.

At block 302, a computing system (e.g., system 400) receives a representation of at least one machine learning model. The received representation can be, for example, an application/state 202 (e.g., an LLM) in FIG. 2. The received representation can include workload components 205₁-205₅ associated with execution of the machine learning model (e.g. LLM).

At block 304, the computing system obtains an initial configuration of a set of configurable hardware elements (e.g., router 101 or tensor compute subsystem 104 in FIG. 1, blocks 204 in FIG. 2, etc.). For example, an initial configuration of a set of configurable hardware elements (e.g., elements 100-106) can include values for a subset of adjustable design parameters and be obtained by the computing system from a user and/or from a default setting or storage. For example, router 101 can be configured with an initial number of ports and tensor compute subsystem 104 can be configured with a default column number. A computing system can also obtain an initial mapping (e.g., mapping 250) of workloads to the set of configurable hardware elements (e.g., elements 100-106). In an example, obtaining the initial mapping can assign different operators of the one machine learning model to a same configurable hardware element (e.g., one of blocks 204₁-204₄). For example, the initial mapping (e.g., mapping 250) can assign workloads 205₁ and 205₅ to a same hardware block 204₁.

At block 306, the computing system can obtain, based on simulation (e.g., chip simulation 207 in FIG. 2) using the initial configuration and the initial mapping, one or more ASIC performance metrics. For example, the computing system can perform chip simulation 207 under the initial configuration and mapping. Chip simulation 207 can then generate performance metrics, such as power, performance, and/or die area (PPA).

At block 308, the computing system can update at least one of the initial configurations or the initial mapping to obtain at least one of an updated configuration of the set of configurable hardware elements (e.g., updated configurations for elements 100-106) or an updated mapping (e.g., updated mapping 250). Determining the updated configuration of the set of configurable hardware elements can include adjusting, without receiving a user input, the respective adjustable design parameters (e.g., parameters associated with blocks 204) based on the one or more ASIC performance metrics obtained from block 306 and the one or more design constraints (e.g., constraints 209). Specifically, with reference to FIGS. 2 and 3, the update can be based on equation 206 that updates parameters θ of policy network 212. Actions 210 produced by policy network 212 can then be used to update a previous hardware configuration (e.g., initial configuration) to an updated hardware configuration and/or update a previous mapping (e.g., initial mapping) to an updated mapping. The updating of hardware configuration can modify parameter values (e.g., number of tensor compute subsystems in node 100). The updating of mapping can modify mapping decisions that bind workload components to the hardware configurations. For example, workload 205₁ may be remapped to block 204₂, instead of 204₁, and the remapping may improve the chip performance to better meet the design objectives. In an example, determining the updated mapping can assign different operators of the machine learning model to a same configurable hardware element (204₁-204₄). For example, the updated mapping (e.g., mapping 250) can assign (or maintain) workloads 205₂, 205₃, and 205₄ to a same hardware block 204₃.

At block 310, the computing system can obtain one or more updated ASIC performance metrics based on simulation (e.g., chip simulation 207) using at least one of the initial configurations, the updated configurations, the initial mapping, or the updated mapping. For example, the computing system can perform chip simulation 207 using the updated configuration and/or updated mapping to produce updated performance information under the constraints 209. In some other examples, obtaining the one or more ASIC performance metrics can include, for example, predicting, by a surrogate approximator, one or more ASIC performance metrics.

At block 312, the computing system can determine at least one of a further updated configuration of the set of configurable hardware elements (e.g., further updated configurations of configurable hardware elements 201) or a further updated mapping (e.g., further updated mapping 250). The determination can be based on the updated ASIC performance metrics obtained from block 310 and the one or more design constraints (e.g., constraints 209). The determination can include providing feedback. The feedback includes a reward value (e.g., reward 208). The reward value can be derived from ASIC performance metrics and design constraints (e.g., constraints 209). The further update can continue to adjust configuration decisions and/or revise mapping. The further update can also be performed such that the reward value (e.g., reward 208) is increased. In some examples, the determination of the further updated configuration of the set of configurable hardware elements and the further updated mapping can further include, for example, evaluating, by a critic network, the reward value based on a target value.

At block 316, the computing system can determine whether a termination condition (e.g., convergence or satisfying design target) is satisfied. For example, convergence can be convergence of one or more performance metrics obtained from chip simulation 207, satisfying design target can be satisfaction of one or more targets specified by the constraints 209. When the termination condition is not satisfied, the computing system returns to block 310 and block 312 to continue iterative simulation-based evaluation and updating. The above process can be repeated as many times as needed.

At block 314, upon satisfaction of the termination condition, the computing system can generate the one or more ASIC design files (e.g., a design file, a layout file, a GDSII format file, etc.) based on at least one of the last updated configuration of the set of configurable hardware elements and the last updated mapping. With continued reference to FIG. 2, the ASIC design files can include a selected configurations of blocks 204₁-204₄ and a selected mapping (e.g., mapping 250) of workload components 205₁-205₅ to those blocks. For example, the generated ASIC design files can include register-transfer level (RTL) design files and/or physical design output files corresponding to the whole ASIC design of ASIC 201.

Various systems, apparatus, and methods described herein may be implemented using digital circuitry, or using one or more computers using well-known computer processors, memory units, storage devices, computer software, and other components. Typically, a computer includes a processor for executing instructions and one or more memories for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least some of the FIGS. 1-3, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

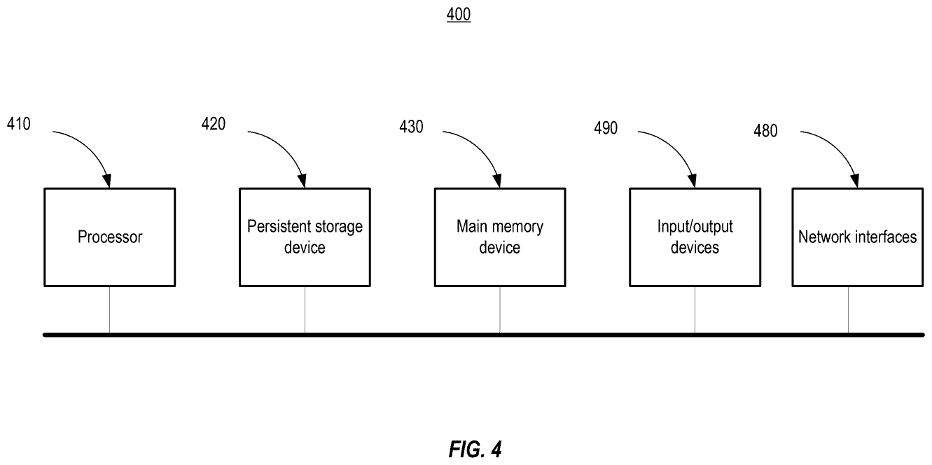

A high-level block diagram of an example apparatus that may be used to implement systems, apparatus and methods described herein is illustrated in FIG. 4. Computing system 400 comprises a processor 410 operatively coupled to a persistent storage device 420 and a main memory device 430. Processor 410 controls the overall operation of apparatus 400 by executing computer program instructions that define such operations. The computer program instructions may be stored in persistent storage device 420, or other computer-readable medium, and loaded into main memory device 430 when execution of the computer program instructions is desired. The method steps of at least some of FIGS. 1-3 can be defined by the computer program instructions stored in main memory device 430 and/or persistent storage device 420 and controlled by processor 410 executing the computer program instructions. For example, the computer program instructions can be implemented as computer executable code programmed by one skilled in the art to perform an algorithm defined by the method steps discussed herein in connection with at least some of FIGS. 1-3. Accordingly, by executing the computer program instructions, the processor 410 executes an algorithm defined by the method steps of these aforementioned figures. Computing system 400 also includes one or more network interfaces 480 for communicating with other devices via a network. Computing system 400 may also include one or more input/output devices 490 that enable user interaction with computing system 400 (e.g., display, keyboard, mouse, speakers, buttons, etc.).

Processor 410 may include both general and special purpose microprocessors and may be the sole processor or one of multiple processors of computing system 400. Processor 410 may comprise one or more central processing units (CPUs), and one or more graphics processing units (GPUs), which, for example, may work separately from and/or multi-task with one or more CPUs to accelerate processing, e.g., for various image processing applications described herein. Processor 410, persistent storage device 420, and/or main memory device 430 may include, be supplemented by, or incorporated in, one or more application-specific integrated circuits (ASICs) and/or one or more field programmable gate arrays (FPGAs).

Persistent storage device 420 and main memory device 430 each comprise a tangible non-transitory computer readable storage medium. Persistent storage device 420, and main memory device 430, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices, semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices.

Input/output devices 490 may include peripherals, such as a printer, scanner, display screen, etc. For example, input/output devices 490 may include a display device such as a cathode ray tube (CRT), plasma or liquid crystal display (LCD) monitor for displaying information to a user, a keyboard, and a pointing device such as a mouse or a trackball by which the user can provide input to apparatus 400.

Any or all of the functions of the systems and apparatuses discussed herein may be performed by processor 410, and/or incorporated in, an apparatus or a system such as node 100. Further, computing system 400 may utilize one or more neural networks or other deep-learning techniques performed by processor 410 or other systems or apparatuses discussed herein.

One skilled in the art will recognize that an implementation of an actual computer or computer system may have other structures and may contain other components as well, and that FIG. 4 is a high-level representation of some of the components of such a computer for illustrative purposes.

The foregoing specification is to be understood as being in every respect illustrative and exemplary, but not restrictive, and the scope of the invention disclosed herein is not to be determined from the specification, but rather from the claims as interpreted according to the full breadth permitted by the patent laws. It is to be understood that the embodiments shown and described herein are only illustrative of the principles of the present invention and that various modifications may be implemented by those skilled in the art without departing from the scope and spirit of the invention. Those skilled in the art could implement various other feature combinations without departing from the scope and spirit of the invention.

What is claimed is:

1. A computer-implemented method for automated generation of one or more application-specific integrated circuit (ASIC) design files, the method being performed by a computing system having at least one processor and memory, and the method comprising:
receiving a representation of at least one machine learning model;
obtaining an initial configuration of a set of configurable hardware elements and an initial mapping of workloads to the set of configurable hardware elements, the workloads being associated with tasks performed during execution of the at least one machine learning model;
obtaining, based on simulation using the initial configuration and the initial mapping, one or more ASIC performance metrics;
updating at least one of the initial configuration or the initial mapping to obtain at least one of an updated configuration of the set of configurable hardware elements or an updated mapping, based on the one or more ASIC performance metrics and one or more design constraints;
iteratively performing, until a termination condition is satisfied:
obtaining one or more updated ASIC performance metrics based on simulation using at least one of: the initial configuration or the updated configuration, or the initial mapping or the updated mapping; and
determining at least one of a further updated configuration of the set of configurable hardware elements or a further updated mapping based on the one or more updated ASIC performance metrics and the one or more design constraints; and
generating the one or more ASIC design files based on at least one of the last updated configuration of the set of configurable hardware elements and the last updated mapping.

2. The method of claim 1, wherein:
each configurable hardware element of the set of configurable hardware elements is associated with one or more adjustable design parameters; and
determining the updated configuration of the set of configurable hardware elements comprises: adjusting, without receiving a user input, the respective adjustable design parameters for at least a subset of the set of configurable hardware elements based on the one or more ASIC performance metrics and the one or more design constraints.

3. The method of claim 2, wherein the set of configurable hardware elements comprises a tensor compute subsystem, a vector compute subsystem, an input/output unit, local memory, and an interconnect router.

4. The method of claim 3, wherein the adjustable design parameters associated with the tensor compute subsystem comprise at least one of at least one of row dimension, column dimension, or quantization.

5. The method of claim 3, wherein the adjustable design parameters associated with the vector compute subsystem comprise at least one of: a vector length, an instruction-fetch size, a queue capacity for pending vector operations, an issue width for dispatching vector operations, a write-back bandwidth, a load-store data width, a number of instruction decoders, a number of reservation stations, a number of read and write ports of register file, a number of scalar execution units, a number of vector execution units, or a number of memory read and write ports.

6. The method of claim 3, wherein the adjustable design parameters associated with the local memory comprise at least one of: a storage capacity of the local memory or a number of access ports of the local memory.

7. The method of claim 3, wherein the adjustable design parameters associated with the interconnect router comprise at least one of: a data-unit width for routed transfers or a number of ports of the interconnect router.

8. The method of claim 2, wherein the set of configurable hardware elements forms a parameterized hardware architecture associated with architecture-level adjustable design parameters,
the architecture-level adjustable design parameters being applicable to the adjustable design parameters associated with individual configurable hardware elements, and comprising at least one of: a compute dimension, a memory capacity, a bandwidth, a data-unit width, a port count, an operating voltage, and an operating frequency.

9. The method of claim 1, wherein receiving the representation of the at least one machine learning model comprises receiving a computation graph formed by subgraphs and operators that are assignable to the set of configurable hardware elements.

10. The method of claim 2, wherein obtaining the initial configuration of the set of configurable hardware elements comprises obtaining values for at least a subset of the adjustable design parameters.

11. The method of claim 1, wherein at least one of obtaining the initial mapping and determining the updated mapping comprises: assigning different operators of the at least one machine learning model to a same configurable hardware element.

12. The method of claim 1, wherein the one or more design constraints relate to at least one of: a power constraint, a performance constraint, and a die area constraint of the ASIC.

13. The method of claim 1, wherein the one or more ASIC performance metrics are composite metrics derived from power, performance, and die area in accordance with the one or more design constraints.

14. The method of claim 1, wherein the termination condition comprises at least one of a convergence condition or a design target.

15. The method of claim 1, wherein iteratively performing the determining of at least one of the further updated configuration of the set of configurable hardware elements or the further updated mapping comprises:
based on the one or more ASIC performance metrics and one or more design constraints, keeping the updated configuration of the set of configurable hardware elements fixed and further updating the updated mapping.

16. The method of claim 2, wherein iteratively performing the determining of at least one of the further updated configuration of the set of configurable hardware elements or the further updated mapping comprises:
based on the one or more ASIC performance metrics and one or more design constraints, further updating the updated configuration of the set of configurable hardware elements to have different values of design parameters and further updating the updated mapping.

17. The method of claim 1, wherein iteratively performing the determining of at least one of the further updated configuration of the set of configurable hardware elements and the further updated mapping comprises:
providing feedback including a reward value derived from the one or more ASIC performance metrics and the one or more design constraints to the updated mapping until the termination condition is satisfied.

18. The method of claim 17, wherein the determining of the further updated mapping comprises further updating the updated mapping to increase the reward value derived from the one or more ASIC performance metrics and the one or more design constraints.

19. The method of claim 17, wherein iteratively performing the determining of at least one of the further updated configuration of the set of configurable hardware elements and the further updated mapping further comprises:
predicting, by a critic network, a candidate reward value based on a target return value and at least one of: the initial configuration or the updated configuration, or the initial mapping or the updated mapping; and
determining the at least one of the further updated configuration of the set of configurable hardware elements and the further updated mapping based on the candidate reward value.

20. The method of claim 1, wherein obtaining the one or more ASIC performance metrics comprises predicting, by a surrogate approximator, one or more ASIC performance metrics.

21. A system for automated generation of one or more application-specific integrated circuit (ASIC) design files, the system comprising:
a processor; and
memory coupled to the processor and storing instructions that, when executed by the processor, cause the system to perform operations comprising:
receiving a representation of at least one machine learning model;
obtaining an initial configuration of a set of configurable hardware elements and an initial mapping of workloads to the set of configurable hardware elements, the workloads being associated with tasks performed during execution of the at least one machine learning model;
obtaining, based on simulation using the initial configuration and the initial mapping, one or more ASIC performance metrics;
determining at least one of an updated configuration of the set of configurable hardware elements and an updated mapping based on the one or more ASIC performance metrics and one or more design constraints;
iteratively performing, until a termination condition is satisfied:
obtaining one or more updated ASIC performance metrics based on simulation using at least one of the updated configuration and the updated mapping; and
determining at least one of a further updated configuration of the set of configurable hardware elements or a further updated mapping based on the one or more updated ASIC performance metrics and the one or more design constraints ; and
generating the one or more ASIC design files based on the last updated configuration of the set of configurable hardware elements and the last updated mapping.
